(19) United States
(12) Patent Application Publication
(10) Pub. No.: US 2026/0051729 A1
(43) Pub. Date: Feb. 19, 2026

(54) Battery Cell Reverse Connection Protection Circuit for A Chip

(71) Applicant: Zhejiang Zgmicro Company Limited, Shaoxing (CN)

(72) Inventors: Hang YIN, Shaoxing (CN); Xin LIU, Shaoxing (CN); Zeming LING, Shaoxing (CN)

(21) Appl. No.: 19/298,700

(22) Filed: Aug. 13, 2025

(30) Foreign Application Priority Data
Aug. 13, 2024 (CN) 202411107258.1
Sep. 26, 2024 (CN) 202411351179.5
Jun. 13, 2025 (CN) 202510792213.0

(51) Int. Cl. H02H 7/18; H01M 10/42; H01M 50/51; H01M 50/574; H01M 50/588; H03K 17/687

(52) U.S. Cl. CPC H02H 7/18; H01M 10/425; H01M 50/51; H01M 50/574; H01M 50/588; H03K 17/6871

(57) ABSTRACT

A battery cell reverse connection protection circuit includes N series-connected battery cells and a target chip. The target chip includes N+1 voltage terminals, a positive electrode of a S-th battery cell among the N battery cells coupled to a S-th voltage terminal among the N+1 voltage terminals, and a negative electrode of the S-th battery cell coupled to a (S+1)-th voltage terminal among the N+1 voltage terminals. The positive electrode is coupled to the S-th voltage terminal through a corresponding anti-reverse connection protection switch, or the negative electrode is coupled to the (S+1)-th voltage terminal through a corresponding anti-reverse connection protection switch. When one of the battery cells is incorrectly coupled to the target chip, the corresponding anti-reverse connection protection switch is turned off, and when one of the battery cells is normally coupled to the target chip, the corresponding anti-reverse connection protection switch is turned on.

### CROSS-REFERENCE OF RELATED APPLICATIONS

The present invention claims priorities of Chinese Patent Application No. 2024111072581 filed in China on Aug. 13, 2024, Chinese Patent Application No. 2024113511795 filed in China on Sep. 26, 2024, and Chinese Patent Application No. 2025107922130 filed in China on Jun. 13, 2025, the entire contents of which are incorporated herein by reference.

### BACKGROUND OF THE INVENTION

### Field of the Invention

The present invention relates to the field of electronic circuit technology, and in particular to a battery cell reverse connection protection circuit for a chip.

### Description of the Related Art

In an assembly process of a battery cell and a battery protection board, there may be an erroneous operation of reverse connection of the battery cell. When the battery cell is reversely coupled, due to forward bias conduction of an equivalent diode path inside a chip on the battery protection board, there may be a risk of the battery protection board being burned or even catching fire. To avoid the risk caused by the reverse connection of the battery cell, the present invention is proposed.

### SUMMARY OF THE INVENTION

The purpose of the present invention is to provide a battery cell reverse connection protection circuit for a chip, which can protect the chip when positive and negative electrodes of the battery cell are reversely coupled, and improve safety performance of electronic devices.

To achieve the purpose, according to one aspect of the present invention, a battery cell reverse connection protection circuit is provided. The battery cell reverse connection protection circuit for a chip comprises: N series-connected battery cells and a target chip, wherein the target chip comprises N+1 external voltage terminals, the N+1 voltage terminals are sorted in descending order of electric potential, the positive electrode of the S-th battery cell among the N battery cells is coupled to the S-th voltage terminal among the N+1 voltage terminals, and the negative electrode of the S-th battery cell is coupled to the (S+1)-th voltage terminal among the N+1 voltage terminals; and, the positive electrode of the S-th battery cell is coupled to the S-th voltage terminal through a corresponding anti-reverse connection protection switch, or, the negative electrode of the S-th battery cell is coupled to the (S+1)-th voltage terminal through a corresponding anti-reverse connection protection switch; wherein, when the battery cell is incorrectly coupled to the target chip, the anti-reverse connection protection switch is turned off, and when the battery cell is normally coupled to the target chip, the anti-reverse connection protection switch is turned on.

According to another aspect of the present invention, a battery cell reverse connection protection circuit is provided. The battery cell reverse connection protection circuit for a chip, comprises: a battery cell and a target chip, wherein the target chip comprises a first voltage terminal and a second voltage terminal; a positive electrode of the battery cell is coupled to the first voltage terminal through a corresponding anti-reverse connection protection switch, or a negative electrode of the battery cell is coupled to the second voltage terminal through a corresponding anti-reverse connection protection switch. When the battery cell is incorrectly coupled to the target chip, the anti-reverse connection protection switch is turned off, and when the battery cell is normally coupled to the target chip, the anti-reverse connection protection switch is turned on.

According to yet another aspect of the present invention, a battery cell reverse connection protection circuit is provided. The battery cell reverse connection protection circuit, comprises: a target chip for coupling with a battery cell, comprising a first voltage terminal and a second voltage terminal; and an anti-reverse connection protection switch. When the battery cell is normally coupled to the target chip, a positive electrode of the battery cell is coupled to the first voltage terminal through the anti-reverse connection protection switch, and a negative electrode of the battery cell is coupled to the second voltage terminal, or the positive electrode of the battery cell is coupled to the first voltage terminal, and the negative electrode of the battery cell is coupled to the second voltage terminal through the anti-reverse connection protection switch; and when the battery cell is incorrectly coupled to the target chip, the anti-reverse connection protection switch is turned off, and when the battery cell is normally coupled to the target chip, the anti-reverse connection protection switch is turned on.

Compared with the prior art, the present invention has following advantages: on the premise of not affecting the use of the circuit, the present invention adds one anti-reverse connection protection switch to each battery cell. The anti-reverse connection protection switch can be externally arranged outside the target chip or integrated inside the target chip. Through the anti-reverse connection protection switch, the risk of damage to the target chip or circuit that may occur due to the forward bias conduction of the equivalent diode path inside the target chip when any battery cell is reversely coupled is eliminated.

There are many other objects, together with the foregoing attained in the exercise of the invention in the following description and resulting in the embodiment illustrated in the accompanying drawings.

### BRIEF DESCRIPTION OF THE DRAWINGS

These and other features, aspects, and advantages of the present invention will become better understood with regard to the following description, appended claims, and accompanying drawings wherein:

FIG. 1 is a circuit diagram of a chip powered by battery cells;

FIG. 2 is a schematic diagram of a battery cell reverse connection protection circuit for a chip according to one embodiment of the present invention;

FIG. 3 is a schematic diagram of the reverse connection protection circuit for multiple battery cells according to one embodiment of the present invention;

FIG. 4 is a schematic diagram of the reverse connection protection circuit for a single battery cell according to one embodiment of the present invention;

FIG. 5 is a schematic diagram of a PMOS-based anti-reverse connection protection switch for a single battery cell according to one embodiment of the present invention;

FIG. 6 is a schematic diagram of an NMOS-based anti-reverse connection protection switch for a single battery cell according to one embodiment of the present invention;

FIG. 7 is a schematic diagram of the battery cell reverse connection protection circuit for a chip according to another embodiment of the present invention;

FIG. 8 is a schematic diagram of another reverse connection protection circuit for multiple battery cells according to one embodiment of the present invention;

FIG. 9 is a schematic diagram of the reverse connection protection circuit with an integrated anti-reverse connection protection switch for one battery cell among multiple battery cells according to one embodiment of the present invention;

FIG. 10 is a schematic diagram of another reverse connection protection circuit with an integrated anti-reverse connection protection switch for one battery cell among multiple battery cells according to one embodiment of the present invention;

FIG. 11 is a schematic diagram of the reverse connection protection circuit with the integrated anti-reverse connection protection switches for four battery cells among multiple battery cells according to one embodiment of the present invention;

FIG. 12 is a schematic diagram of another reverse connection protection circuit with the integrated anti-reverse connection protection switches for four battery cells among multiple battery cells according to one embodiment of the present invention;

FIG. 13 is a schematic diagram of yet another reverse connection protection circuit with the integrated anti-reverse connection protection switches for four battery cells among multiple battery cells according to one embodiment of the present invention;

FIG. 14 is a schematic diagram of still another reverse connection protection circuit with the integrated anti-reverse connection protection switches for four battery cells among multiple battery cells according to one embodiment of the present invention;

FIG. 15 is a schematic diagram of another reverse connection protection circuit for a single battery cell according to one embodiment of the present invention;

FIG. 16 is a schematic diagram of a PMOS-based anti-reverse connection protection switch of a single battery cell according to one embodiment of the present invention;

FIG. 17 is a schematic diagram of an NMOS-based anti-reverse connection protection switch of a single battery cell is an NMOS transistor according to one embodiment of the present invention;

FIG. 18 is a schematic circuit diagram of an anti-reverse connection power chip according to one embodiment of the present invention;

FIG. 19 is a schematic circuit diagram of another anti-reverse connection power chip according to one embodiment of the present invention;

FIG. 20 is a schematic circuit diagram of yet another anti-reverse connection power chip according to one embodiment of the present invention; and FIG. 21 is a schematic diagram of a bulk selection circuit according to one embodiment of the present invention.

### DETAILED DESCRIPTION OF THE PREFERRED EMBODIMENTS

The detailed description of the invention is presented largely in terms of procedures, operations, logic blocks, processing, and other symbolic representations that directly or indirectly resemble the operations of data processing devices that may or may not be coupled to networks. These process descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be comprised in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations in the invention.

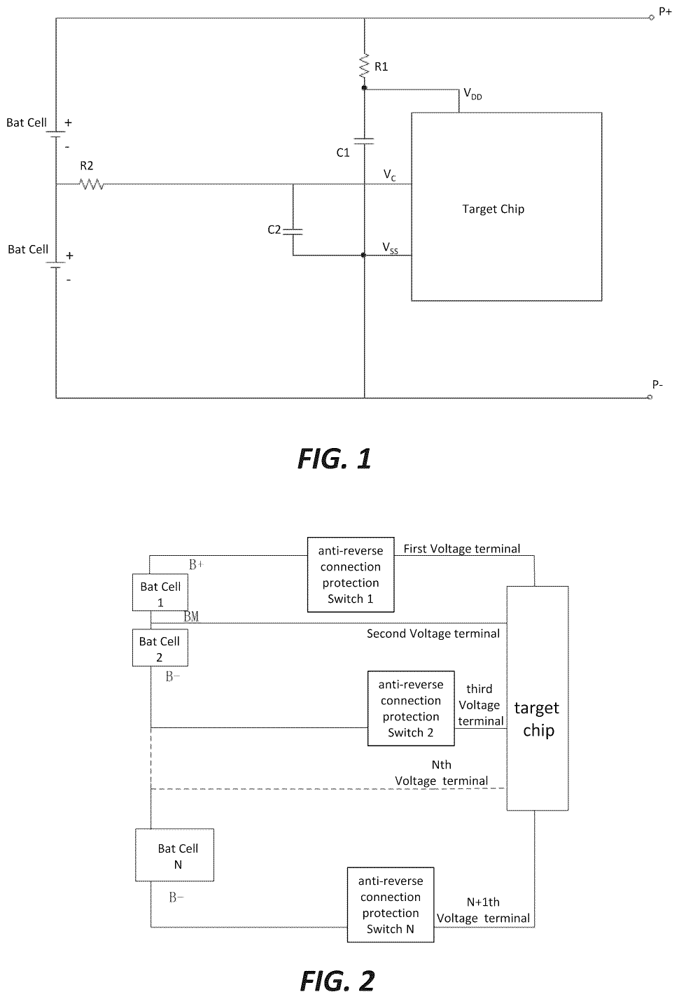

FIG. 1 is a circuit diagram of a chip powered by battery cells. As shown in FIG. 1, under normal conditions, a protected target chip is powered by the two battery cells, and the target chip controls charging and discharging of the battery cells. The target chip is a type of battery protection chip. During an assembly process of two battery cells and the target chip, there may be an incorrect connection where the two battery cells are reversely coupled. When the battery cells are reversely coupled, due to forward bias conduction of an equivalent diode path inside the target chip, the target chip may not operate normally, be burned, or even cause the entire circuit to catch fire.

To avoid the risks caused by the incorrect connection of the battery cells, this specification proposes a battery cell reverse connection protection circuit for a chip. FIG. 2 is a schematic diagram of a battery cell reverse connection protection circuit for a chip according to one embodiment of the present invention. As shown in FIG. 2, the circuit comprises: N series-connected battery cells and a target chip, wherein the target chip comprises N+1 external voltage terminals sorted in descending order of electric potential. The N battery cells comprise a S-th battery cell, a positive electrode of the S-th battery cell is coupled to the S-th voltage terminal, and a negative electrode of the S-th battery cell is coupled to the (S+1)-th voltage terminal, with the electric potential of the S-th voltage terminal being higher than that of the (S+1)-th voltage terminal; the positive electrode of the S-th battery cell is coupled to the S-th voltage terminal through a corresponding anti-reverse connection protection switch, or the negative electrode of the S-th battery cell is coupled to the (S+1)-th voltage terminal through a corresponding anti-reverse connection protection switch. When the battery cell is incorrectly coupled to the target chip, the anti-reverse connection protection switch is turned off, and when the battery cell is normally coupled to the target chip, the anti-reverse connection protection switch is turned on.

In one embodiment, the anti-reverse connection protection switch corresponding to the positive electrode of the S-th battery cell is a PMOS transistor, or the anti-reverse connection protection switch corresponding to the negative electrode of the S-th battery cell is an NMOS transistor. Specifically, a source of the PMOS transistor is coupled to the S-th voltage terminal, a drain of the PMOS transistor is coupled to the positive electrode of the S-th battery cell, and a gate of the PMOS transistor is coupled to the (S+1)-th voltage terminal; a source of the NMOS transistor is coupled to the (S+1)-th voltage terminal, a drain of the NMOS transistor is coupled to the negative electrode of the S-th battery cell, and a gate of the NMOS transistor is coupled to the S-th voltage terminal.

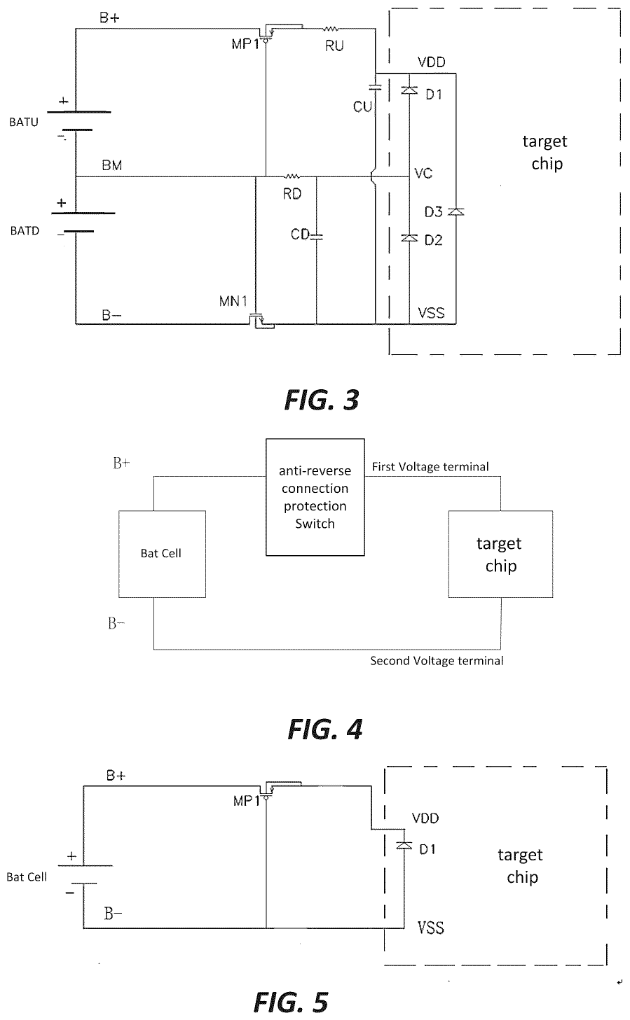

In different embodiments, the battery cells used for power supply can be a single battery cell or multiple series-connected battery cells. FIG. 3 is a schematic diagram of the reverse connection protection circuit for multiple battery cells according to one embodiment of the present invention. As shown in FIG. 3, a dashed line range is an internal area of the protected target chip. In this embodiment, the target chip is powered only by two series-connected battery cells (for example, BATU and BATD). The positive electrode of BATU is coupled to a drain of the PMOS transistor MP1, a source of the PMOS transistor MP1 is coupled to a power supply voltage terminal VDD exposed outside the target chip, a gate of the PMOS transistor MP1 is coupled to a coupling line between the negative electrode BM of BATU and an intermediate input terminal VC of the two batteries of the target chip. The negative electrode of BATD is coupled to a drain of the NMOS transistor MN1, a source of MN1 is coupled to the power supply ground terminal VSS exposed outside the target chip, and a gate of MN1 is coupled to the coupling line between the positive electrode BM of BATD and the intermediate input terminal VC of the two batteries of the target chip. When both battery cells are normally coupled, MP1 and MN1 are turned on, allowing the battery cells to supply power to the protection circuit normally, and three equivalent diodes D1, D2, and D3 are all in a reverse bias cut-off state. Assuming that BATU is reversely coupled and BATD is normally coupled, the potential of B+ is lower than that of BM, and BM becomes the highest potential node in the entire circuit. Since the source of MP1 is coupled to a right side, the MP1 transistor is cut off and there is no forward-biased body diode path in MP1, the discharge path of the reversely coupled BATU is disconnected, no large current flows through the equivalent diode D1, and the battery target chip is safe.

Assuming that BATU is normally coupled and BATD is reversely coupled, the potential of B− is higher than that of BM, and BM becomes the lowest potential node in the entire circuit. Since the source of MN1 is coupled to the right side, the MN1 transistor is cut off and there is no forward-biased body diode path in MN1, the discharge path of the reversely coupled BATD is disconnected. No large current flows through the equivalent diode D2, and the target chip is safe. Assuming that both BATU and BATD are reversely coupled, the potential of B− is the highest, the potential of B+ is the lowest, and the potential of BM is in the middle. For MP1 to be turned on, the potential of VDD must be higher than that of BM, and for MN1 to be turned on, the potential of VSS must be lower than that of BM. If the above conditions are met, it will inevitably cause D1, D2, and D3 to be in the reverse bias cut-off state. It can be seen that when both BATU and BATD are reversely coupled, the battery cell discharge path is cut off.

It should be noted that in different specific examples, resistors RU and RD may or may not exist. In different examples, the gate of the PMOS transistor MP1 or the NMOS transistor MN1 can be coupled to left or right end of the resistor RD. In different examples, capacitors CU and CD may or may not exist. The dashed line range is an internal area of the target chip, wherein D1, D2, and D3 are equivalent diodes of internal electrostatic protection element ESD of the target chip. When the battery cell is reversely coupled, any of the equivalent diodes D1, D2, and D3 will be forward-biased and conducting. In different embodiments, other circuits that play the same role can be used, which is not limited in this specification.

This is just one embodiment, and it can be extended to examples where anti-reverse connection switches corresponding to each of more than two series-connected battery cells are externally arranged.

FIG. 4 is a schematic diagram of the reverse connection protection circuit for a single battery cell according to one embodiment of the present invention. As shown in FIG. 4, the circuit comprises: a battery cell and a target chip, wherein the target chip comprises an external first voltage terminal and an external second voltage terminal, and the electric potential of the first voltage terminal is higher than that of the second voltage terminal. The positive electrode of the battery cell is coupled to the first voltage terminal through a corresponding anti-reverse connection protection switch, or the negative electrode of the battery cell is coupled to the second voltage terminal through a corresponding anti-reverse connection protection switch; wherein, the anti-reverse connection protection switch corresponding to the positive or negative electrode of the battery cell is turned on when the battery cell is normally coupled, and turned off when the battery cell is reversely coupled.

In one embodiment, the anti-reverse connection protection switch corresponding to the positive electrode of the battery cell is a PMOS transistor, a source of the PMOS transistor is coupled to the first voltage terminal, a drain of the PMOS transistor is coupled to the positive electrode of the corresponding battery cell, and a gate of the PMOS transistor is coupled to the second voltage terminal. The anti-reverse connection protection switch corresponding to the negative electrode of the battery cell is an NMOS transistor, a source of the NMOS transistor is coupled to the second voltage terminal, a drain of the NMOS transistor is coupled to the negative electrode of the battery cell, and a gate of the NMOS transistor is coupled to the first voltage terminal.

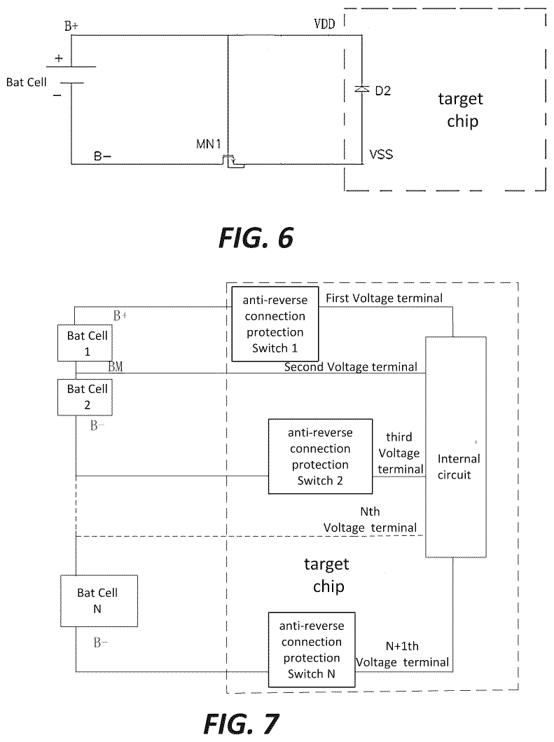

FIG. 5 is a schematic diagram of a PMOS-based anti-reverse connection protection switch for a single battery cell according to one embodiment of the present invention. As shown in FIG. 5, the positive electrode of BAT is coupled to a drain of the PMOS transistor MP1, a source of MP1 is coupled to the power supply voltage terminal VDD exposed outside the target chip, and a gate of MP1 is coupled to the coupling line between the negative electrode of BAT and the power supply ground terminal VSS. Assuming that BAT is reversely coupled, the potential of B+ is lower than that of B−, and B− becomes the highest potential node in the entire circuit. Since the source of MP1 is coupled to the right side, the MP1 transistor is cut off and there is no forward-biased body diode path in MP1, the discharge path of the reversely coupled BAT is disconnected, no large current flows through the equivalent diode D1, and the target chip is safe. FIG. 6 is a schematic diagram of an NMOS-based reverse connection protection switch for a single battery cell according to one embodiment of the present invention. As shown in FIG. 6, the negative electrode of BAT is coupled to a drain of the NMOS transistor MN1, a source of MN1 is coupled to the power supply ground terminal VSS exposed outside the target chip, and a gate of MN1 is coupled to the coupling line between the positive electrode of BAT and the power supply voltage terminal VDD. Assuming that BAT is reversely coupled, the potential of B− is higher than that of B+, and B+ becomes the lowest potential node in the entire circuit. Since the source of MN1 is coupled to the right side, the MN1 transistor is cut off and there is no forward-biased body diode path in MN1, the discharge path of the reversely coupled BAT is disconnected. No large current flows through the equivalent diode D2, and the target chip is safe.

FIG. 7 is a schematic diagram of the battery cell reverse connection protection circuit for a chip according to another embodiment of the present invention. As shown in FIG. 7, the dashed line range is the internal area of the target chip, and an internal circuit is a main circuit in the target chip. The circuit comprises: N series-connected battery cells and a target chip, the target chip comprises N+1 voltage terminals sorted in descending order of electric potential, the positive electrode of the S-th battery cell among the N battery cells is coupled to the S-th voltage terminal among the N+1 voltage terminals, and the negative electrode of the S-th battery cell is coupled to the (S+1)-th voltage terminal among the N+1 voltage terminals; and, the positive electrode of the S-th battery cell is coupled to the S-th voltage terminal through a corresponding anti-reverse connection protection switch integrated into the target chip, and the S-th voltage terminal is integrated into the target chip, or, the negative electrode of the S-th battery cell is coupled to the (S+1)-th voltage terminal through a corresponding anti-reverse connection protection switch integrated into the target chip, and the (S+1)-th voltage terminal is integrated into the target chip. The anti-reverse connection protection switch corresponding to the positive or negative electrode of the S-th battery cell is turned on when the S-th battery cell is normally coupled, and turned off when the S-th battery cell is reversely coupled.

In one embodiment, the anti-reverse connection protection switch corresponding to the positive electrode of the S-th battery cell and integrated into the target chip is a PMOS transistor, and the anti-reverse connection protection switch corresponding to the negative electrode of the S-th battery cell and integrated into the target chip is an NMOS transistor. Specifically, the source of the PMOS transistor is coupled to the S-th voltage terminal, the drain of the PMOS transistor is coupled to the positive electrode of the S-th battery cell, and the gate of the PMOS transistor is coupled to the (S+1)-th voltage terminal. The source of the NMOS transistor is coupled to the (S+1)-th voltage terminal, the drain of the NMOS transistor is coupled to the negative electrode of the S-th battery cell, and the gate of the NMOS transistor is coupled to the S-th voltage terminal.

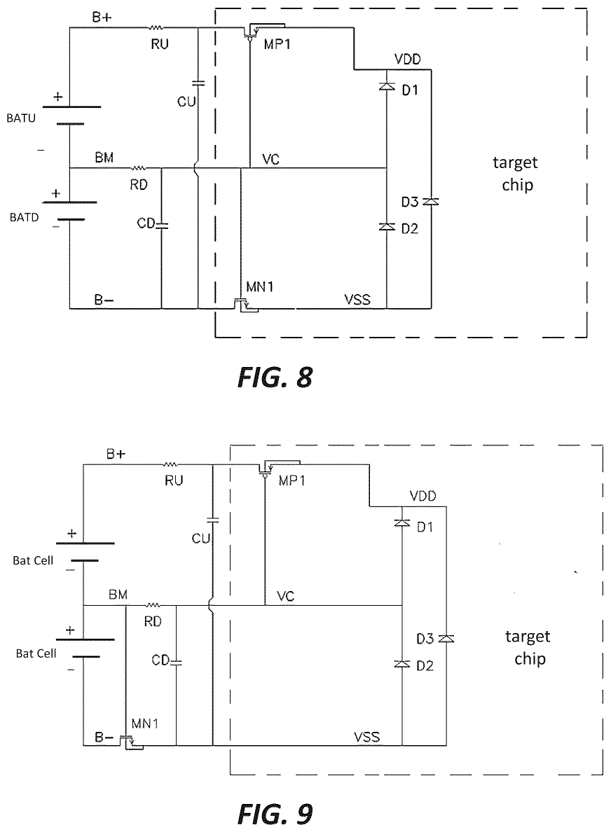

FIG. 8 is a schematic diagram of another reverse connection protection circuit for multiple battery cells according to one embodiment of the present invention. As shown in FIG. 8, the dashed line range is the internal area of the target chip. In this embodiment, the target chip is powered only by two series-connected battery cells (for example, BATU and BATD). MP1 and MN1 are integrated inside the target chip. The positive electrode of BATU is coupled to the drain of the PMOS transistor MP1, the source of MP1 is coupled to the power supply voltage terminal VDD exposed inside the target chip, the gate of MP1 is coupled to the internal coupling line between the negative electrode BM of BATU and the intermediate input terminal VC of the two batteries of the target chip. The negative electrode of BATD is coupled to the drain of the NMOS transistor MN1, the source of MN1 is coupled to the power supply ground terminal VSS exposed inside the target chip, and the gate of MN1 is coupled to the internal coupling line between the positive electrode BM of BATD and the intermediate input terminal VC of the two batteries of the target chip. When both battery cells are normally coupled, MP1 and MN1 are turned on, allowing the battery cells to supply power to the protection circuit normally, and the three equivalent diodes D1, D2, and D3 are all in the reverse bias cut-off state. Assuming that BATU is reversely coupled and BATD is normally coupled, the potential of B+ is lower than that of BM, and BM becomes the highest potential node in the entire circuit. Since the source of MP1 is coupled to the right side, the MP1 transistor is turned off and there is no forward-biased body diode path in MP1, the discharge path of the reversely coupled BATU is disconnected, no large current flows through the equivalent diode D1, and the target chip is safe. Assuming that BATU is normally coupled and BATD is reversely coupled, the potential of B− is higher than that of BM, and BM becomes the lowest potential node in the entire circuit. Since the source of MN1 is coupled to the right side, the MN1 transistor is turned off and there is no forward-biased body diode path in MN1, the discharge path of the reversely coupled BATD is disconnected. No large current flows through the equivalent diode D2, and the target chip is safe. Assuming that both BATU and BATD are reversely coupled, the potential of B− is the highest, the potential of B+ is the lowest, and the potential of BM is in the middle. For MP1 to be turned on, the potential of VDD must be higher than that of BM, and for MN1 to be turned on, the potential of VSS must be lower than that of BM. If the above conditions are met, it will inevitably cause D1, D2, and D3 to be in the reverse bias cut-off state. It can be seen that when both BATU and BATD are reversely coupled, the battery cell discharge path is cut off.

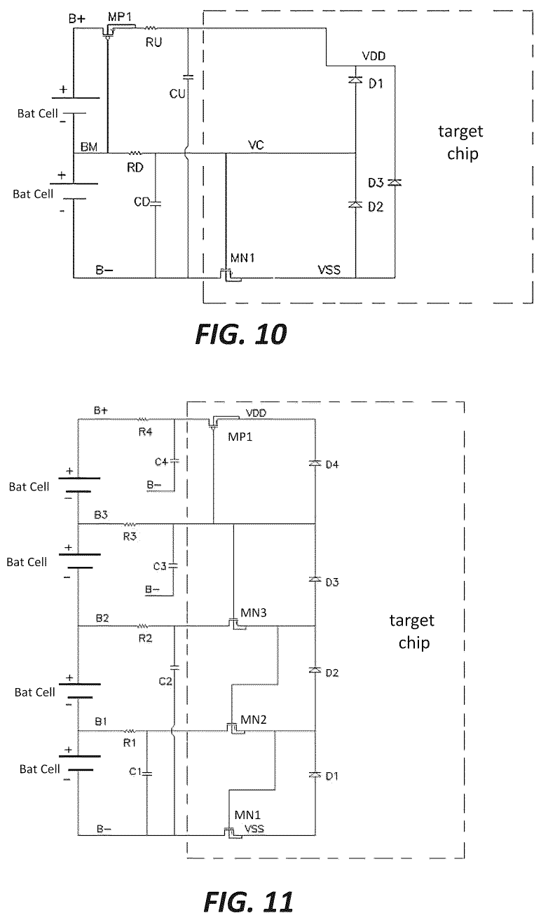

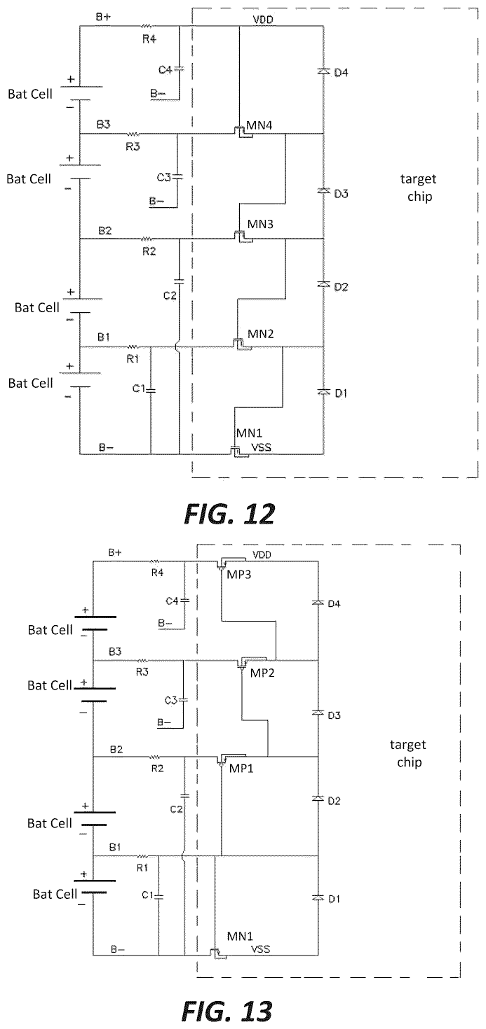

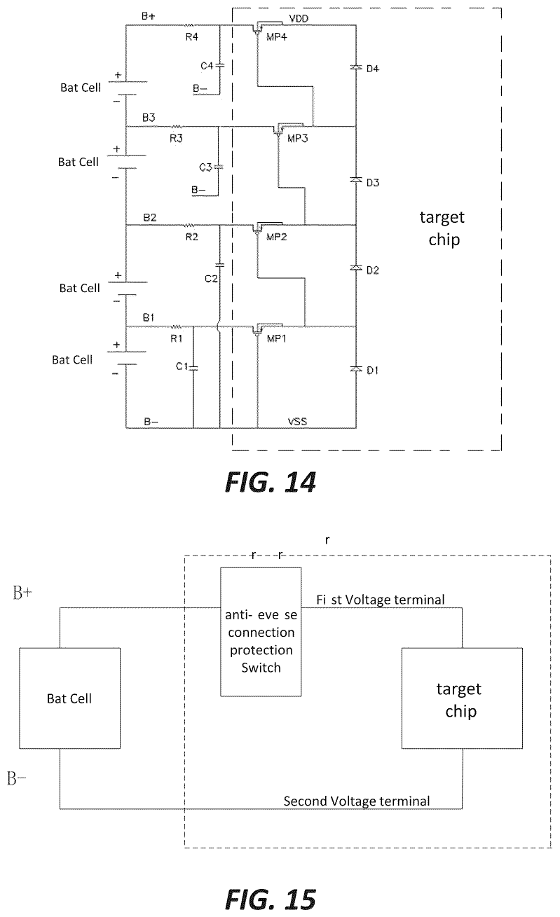

This is just one embodiment, and it can be extended to, for example, FIG. 9 is a schematic diagram of the reverse connection protection circuit with an integrated anti-reverse connection protection switch for one battery cell among multiple battery cells according to one embodiment of the present invention, FIG. 10 is a schematic diagram of another reverse connection protection circuit with an integrated anti-reverse connection protection switch for one battery cell among multiple battery cells according to one embodiment of the present invention, FIG. 11 is a schematic diagram of the reverse connection protection circuit with the integrated anti-reverse connection protection switches for four battery cells among multiple battery cells according to one embodiment of the present invention, FIG. 12 is a schematic diagram of another reverse connection protection circuit with the integrated anti-reverse connection protection switches for four battery cells among multiple battery cells according to one embodiment of the present invention, FIG. 13 is a schematic diagram of yet another reverse connection protection circuit with the integrated anti-reverse connection protection switches for four battery cells among multiple battery cells according to one embodiment of the present invention, FIG. 14 is a schematic diagram of still another reverse connection protection circuit with the integrated anti-reverse connection protection switches for four battery cells among multiple battery cells according to one embodiment of the present invention, or examples where the anti-reverse connection switch corresponding to each of more than two series-connected battery cells is built-in MOS transistors.

FIG. 15 is a schematic diagram of another reverse connection protection circuit for a single battery cell according to one embodiment of the present invention. As shown in FIG. 15, the dashed line range is the internal area of the target chip, and the internal circuit is the main circuit in the target chip. The circuit comprises: a battery cell and a target chip, the target chip comprises a built-in first voltage terminal and a built-in second voltage terminal, the electric potential of the first voltage terminal is higher than that of the second voltage terminal, the positive electrode of the battery cell is coupled to the first voltage terminal through a corresponding anti-reverse connection protection switch integrated into the target chip, or the negative electrode of the battery cell is coupled to the second voltage terminal through a corresponding anti-reverse connection protection switch integrated into the target chip. The anti-reverse connection protection switch corresponding to the positive or negative electrode of the battery cell is turned on when the battery cell is normally coupled, and turned off when the battery cell is reversely coupled.

In one embodiment, the anti-reverse connection protection switch corresponding to the positive electrode of the battery cell and integrated into the target chip is a PMOS transistor, the source of the PMOS transistor is coupled to the first voltage terminal, the drain of the PMOS transistor is coupled to the positive electrode of the corresponding battery cell, and the gate of the PMOS transistor is coupled to the second voltage terminal. In another embodiment, the anti-reverse connection protection switch corresponding to the negative electrode of the battery cell and integrated into the target chip is an NMOS transistor, the source of the NMOS transistor is coupled to the second voltage terminal, the drain of the NMOS transistor is coupled to the negative electrode of the corresponding cell, and the gate of the NMOS transistor is coupled to the first voltage terminal.

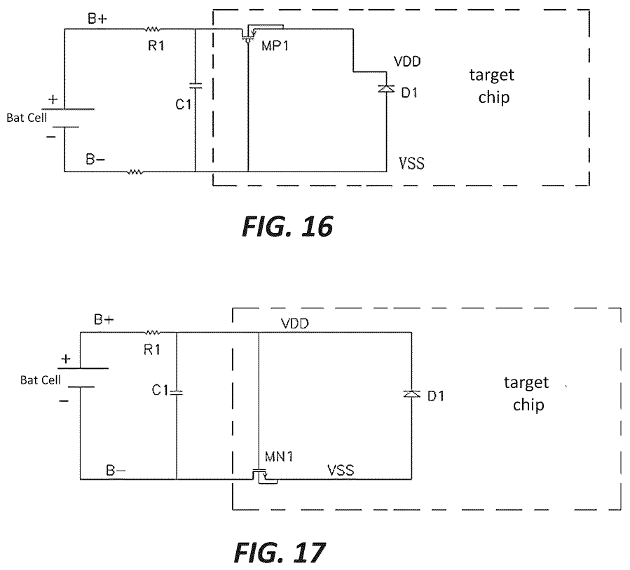

FIG. 16 is a schematic diagram of another case where the reverse connection protection switch of a single battery cell is a PMOS transistor MP1 according to one embodiment of the present invention. As shown in FIG. 16, the positive electrode of BAT cell is coupled to the drain of the PMOS transistor MP1, the source of MP1 is coupled to the internal power supply voltage terminal VDD of the target chip, and the gate of MP1 is coupled to the internal coupling line between the negative electrode of BAT cell and the power supply ground terminal VSS. Assuming that the BAT cell is reversely coupled, the potential of B+ is lower than that of B−, and B− becomes the highest potential node in the entire circuit. Since the source of MP1 is coupled to the right side, the MP1 transistor is cut off and there is no forward-biased body diode path in MP1, the discharge path of the reversely coupled the BAT cell is disconnected, no large current flows through the equivalent diode D1, and the target chip is safe. FIG. 17 is a schematic diagram of another case where the reverse connection protection switch of a single battery cell is an NMOS transistor MN1 according to one embodiment of the present invention. As shown in FIG. 17, the negative electrode of the BAT cell is coupled to the drain of the NMOS transistor MN1, the source of MN1 is coupled to the internal power supply ground terminal VSS of the target chip, and the gate of MP1 is coupled to the internal coupling line between the positive electrode of the BAT cell and the power supply voltage terminal VDD. Assuming that the BAT cell is reversely coupled, the potential of B− is higher than that of B+, and B+ becomes the lowest potential node in the entire circuit. Since the source of MN1 is coupled to the right side, the transistor MN1 is cut off and there is no forward-biased body diode path in the transistor MN1, the discharge path of the reversely coupled the BAT cell is disconnected. No large current flows through the equivalent diode D1, and the target chip is safe.

The present invention provides an anti-reverse connection power chip. The anti-reverse connection power chip comprises: a positive power supply terminal for coupling to a positive electrode of a battery cell; an external negative power supply terminal for coupling to a negative electrode of the battery cell; an internal negative power supply terminal; an anti-reverse connection protection switch coupled between the external negative power supply terminal and the internal negative power supply terminal, with its control terminal coupled to the positive power supply terminal; a control component coupled between the positive power supply terminal and the internal negative power supply terminal, which comprises a control output terminal; a power switch having one conductive terminal coupled to the external negative power supply terminal, and a control terminal coupled to the control output terminal of the control component. When the battery cell is reversely coupled to the anti-reverse connection power chip, the anti-reverse connection protection switch is turned off; when the battery cell is correctly coupled to the anti-reverse connection power chip, the anti-reverse connection protection switch is turned on.

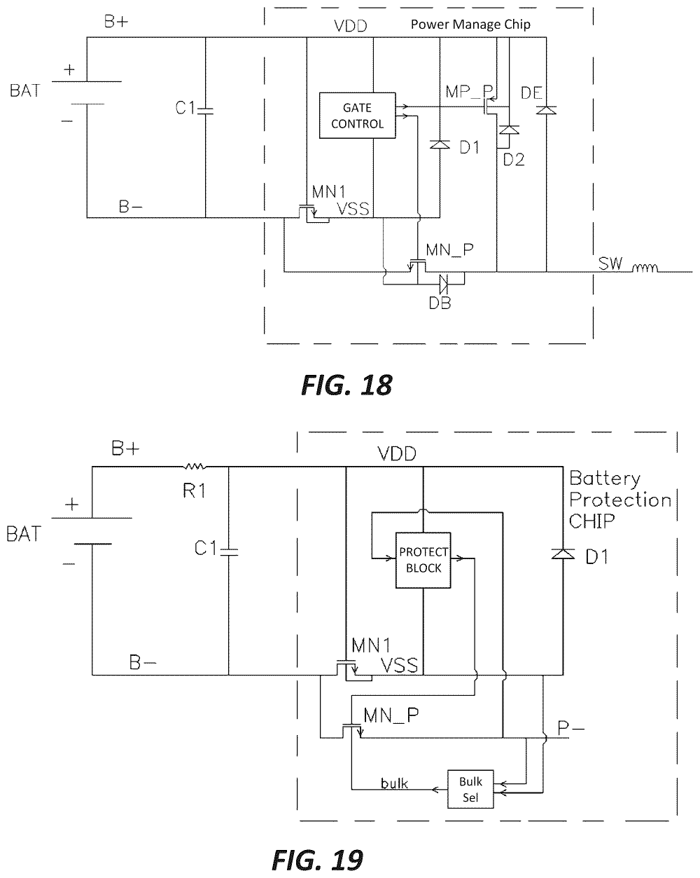

Exemplarily, in FIGS. 18-20, dashed boxes can be understood as an anti-reverse connection power chip according to the present invention.

Specifically, the aforementioned anti-reverse connection power chip can be used as a power management chip or a power protection chip, and applied in vehicle-mounted systems, robots, or artificial intelligence systems.

The positive power supply terminal and the external negative power supply terminal can be understood as two contact terminals in the anti-reverse connection power chip for coupling to the battery cell. As shown in FIGS. 18-20, the aforementioned battery cell can be understood as BAT in FIGS. 18-20, the aforementioned positive power supply terminal can be understood as VDD node in FIGS. 18-20, the aforementioned external negative power supply terminal can be understood as B− node in FIGS. 18-20, and the aforementioned internal negative power supply terminal can be understood as VSS node.

Specifically, when the battery cell (BAT) is correctly coupled to the anti-reverse connection power chip (dashed box), the positive power supply terminal (VDD node) is coupled to the positive electrode of the battery cell, and the external negative power supply terminal (B− node) is coupled to the negative electrode of the battery cell. In this case, the potential of the positive power supply terminal (VDD node) is higher than that of the external negative power supply terminal (B− node).

When the battery cell (BAT) is reversely coupled to the anti-reverse connection power chip (dashed box), the positive power supply terminal (VDD node) is coupled to the negative electrode of the battery cell, and the external negative power supply terminal (B− node) is coupled to the positive electrode of the battery cell. In this case, the potential of the positive power supply terminal (VDD node) is lower than that of the external negative power supply terminal (B− node).

In the present invention, the anti-reverse connection protection switch is arranged between the external negative power supply terminal and the internal negative power supply terminal, and the control terminal of the anti-reverse connection protection switch is coupled to the positive power supply terminal. Thus, the control terminal can detect the potential of the positive power supply terminal (which is used to connect to the positive electrode of the battery cell) to determine whether the battery cell is reversely coupled to the anti-reverse connection power chip. When a reverse connection occurs, the anti-reverse connection protection switch is turned off to achieve potential isolation between the external negative power supply terminal and the internal negative power supply terminal. This avoids occurrence of a large current path inside the anti-reverse connection power chip when the battery cell is reversely coupled to the chip, thereby preventing the chip from being burned due to the large current path and ensuring the safe use of the anti-reverse connection power chip.

In one embodiment, the anti-reverse connection protection switch is a MOS transistor MN1. One conductive terminal of the MOS transistor MN1 is coupled to the internal negative power supply terminal, the other conductive terminal of the MOS transistor MN1 is coupled to the external negative power supply terminal, a gate of the MOS transistor MN1, as the control terminal of the anti-reverse connection protection switch, is coupled to the positive power supply terminal, and a bulk of the MOS transistor MN1 is coupled to the internal negative power supply terminal.

The power switch is a MOS transistor MN_P. One conductive terminal of the MOS transistor MN_P is coupled to the external negative power supply terminal, and a gate of the MOS transistor MN_P, as the control terminal, is coupled to the output terminal of the control component.

As shown in FIGS. 18-20, MN1 in FIGS. 18-20 can be understood as the aforementioned anti-reverse connection protection switch (i.e., MOS transistor MN1), and MN_P in FIGS. 18-20 can be understood as the aforementioned power switch (hereinafter also referred to as the first power switch, i.e., MOS transistor MN_P).

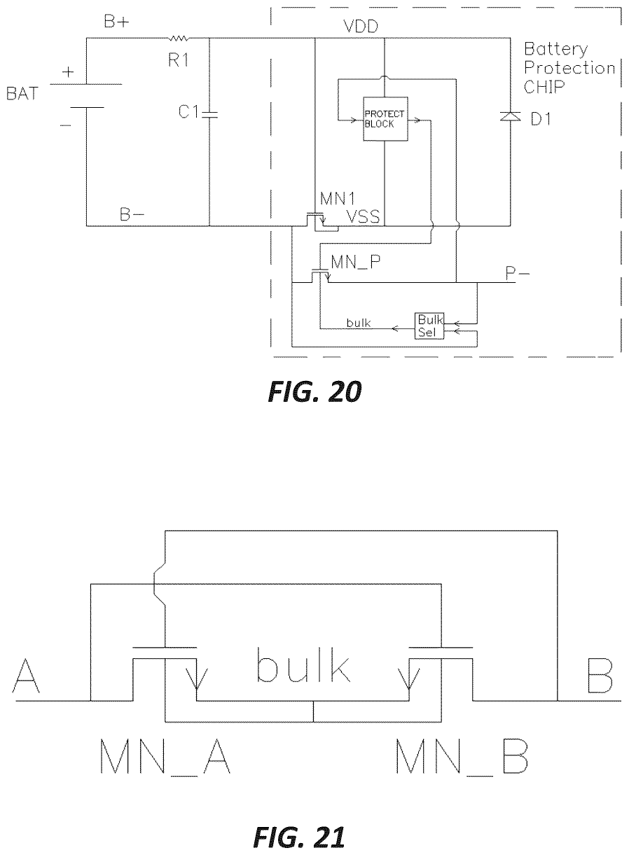

As shown in FIGS. 18-20, when the battery cell (BAT) is correctly coupled to the anti-reverse connection power chip (dashed box), the potential of the positive power supply terminal (VDD node) is higher than that of the external negative power supply terminal (B− node). Since the gate of the anti-reverse connection protection switch (MN1) is coupled to the positive power supply terminal (VDD node), the anti-reverse connection protection switch (MN1) will be turned on under the action of the high potential of the positive power supply terminal (VDD node). When the anti-reverse connection protection switch (MN1) is turned on, the potential of the internal negative power supply terminal (VSS node) and that of the external negative power supply terminal (B− node) will be approximately the same. For the power switch (MN_P), when it receives a high-potential control signal from the output terminal of the control component (GATE CONTROL in FIG. 18, PROTECT BLOCK in FIGS. 19-20), the power switch (MN_P) will be turned on; when it receives a low-potential control signal from the output terminal of the control component, the power switch (MN_P) will be turned off.

When the battery cell (BAT) is reversely coupled to the anti-reverse connection power chip (dashed box), the potential of the positive power supply terminal (VDD node) is lower than that of the external negative power supply terminal (B− node). Since the gate of the anti-reverse connection protection switch (MN1) is coupled to the positive power supply terminal (VDD node), the anti-reverse connection protection switch (MN1) will be turned off under the action of the low potential of the positive power supply terminal (VDD node), resulting in potential isolation between the internal negative power supply terminal (VSS node) and the external negative power supply terminal (B− node). Even if the external negative power supply terminal (B− node) is at a high potential, the internal negative power supply terminal (VSS node) can still maintain a low potential (tending to be consistent with the potential of the positive power supply terminal (VDD node)). For the power switch (MN_P), since the control component coupled to its gate is in an environment with low potential (both VSS node and VDD node are at low potential), the control component cannot send a high-potential control signal to the power switch (MN_P), which causes the power switch (MN_P) to be turned off. This design can turn off both the anti-reverse connection protection switch (MN1) and the power switch (MN_P) when the battery cell (BAT) is reversely coupled to the anti-reverse connection power chip (dashed box), and keep all parts of the anti-reverse connection power chip isolated from the high-potential external negative power supply terminal (B− node) (i.e., all parts of the anti-reverse connection power chip maintain a low potential). Thus, it avoids the occurrence of a large current path when the anti-reverse connection power chip is reversely coupled to the battery cell, further prevents the chip from being burned due to the large current path, and effectively ensures the safe use of the anti-reverse connection power chip.

In one example, both the MOS transistor MN1 and the MOS transistor MN_P are N-Metal-Oxide-Semiconductor (NMOS) transistors.

Using NMOS transistors as MOS transistor MN1 and MOS transistor MN_P can utilize the advantages of NMOS transistors such as low on-resistance, sensitive switching speed, good thermal performance, easy driving, low cost, high current-carrying capacity, and high voltage-carrying capacity, thereby realizing sensitive control of the switches of the anti-reverse connection power chip at a low cost.

In one embodiment, as shown in FIG. 18, the anti-reverse connection power chip further comprises a second power switch, wherein the aforementioned power switch is referred to as the first power switch.

The first power switch is a MOS transistor MN_P. One conductive terminal of the MOS transistor MN_P is coupled to the external negative power supply terminal, the gate of the MOS transistor MN_P, as the control terminal, is coupled to one output terminal of the control component, the other conductive terminal of the MOS transistor MN_P is coupled to a node SW, and the bulk of the MOS transistor MN_P is coupled to the internal negative power supply terminal.

The second power switch is a MOS transistor MP_P. One conductive terminal of the MOS transistor MP_P is coupled to the positive power supply terminal, a gate of the MOS transistor MP_P, as the control terminal, is coupled to another control output terminal of the control component, the other conductive terminal of the MOS transistor MP_P is coupled to node SW, and a bulk of the MOS transistor MN_P is coupled to the positive power supply terminal.

The node SW is coupled to an inductor.

Further, as shown in FIG. 18, the control component converts an input voltage into an output voltage by controlling the first power switch and the second power switch to be turned on alternately.

In this embodiment, the anti-reverse connection power chip can serve as a power management chip, and the internal circuit of the anti-reverse connection power chip can be approximately understood as a buck circuit.

In one embodiment, as shown in FIG. 19, the other conductive terminal of the MOS transistor MN_P is coupled to a negative power output terminal P−. The anti-reverse connection power chip further comprises a bulk selection circuit. One input terminal of the bulk selection circuit is coupled to the negative power output terminal P−, the other input terminal of the bulk selection circuit is coupled to the internal negative power supply terminal or the external negative power supply terminal, an output terminal of the bulk selection circuit is coupled to a bulk of the MOS transistor MN_P, and the bulk selection circuit selects lower potential from the two input terminals and provides it to the bulk of the MOS transistor MN_P.

The negative power output terminal P−is coupled to the input terminal of the control component.

The control component realizes charge and discharge protection by controlling conduction or disconnection of the power switch.

In this embodiment, the anti-reverse connection power chip can exist as a power protection chip. In this case, based on configuration of the bulk selection circuit, the lower potential from the two input terminals is selected for the bulk of the MOS transistor MN_P, so as to ensure that the MOS transistor MN_P can normally cut off the discharge path and the charge path.

Herein, the charge path should be understood as a path for charging/powering the MOS transistor MN_P, and the discharge path is a path for powering various components in the anti-reverse connection power chip through the battery cell.

The other input terminal of the bulk selection circuit is coupled to the internal negative power supply terminal or the external negative power supply terminal, so as to ensure that the MOS transistor MN_P can effectively control the conduction or cut-off of the current path between the external negative power supply terminal and the node SW, while supporting more flexible circuit design to adapt to usage requirements in different scenarios, making the application of the protection circuit of the present invention more flexible.

Further, the bulk selection circuit comprises MOS transistors MN_A and MN_B.

One conductive terminal of the MOS transistor MN_A, as one input terminal of the bulk selection circuit, is coupled to the negative power output terminal P−; the other conductive terminal of the MOS transistor MN_A is coupled to the bulk of the MOS transistor MN_P; a gate of the MOS transistor MN_A is coupled to the internal negative power supply terminal or the external negative power supply terminal.

One conductive terminal of the MOS transistor MN_B, as the other input terminal of the bulk selection circuit, is coupled to the internal negative power supply terminal or the external negative power supply terminal; the other conductive terminal of the MOS transistor MN_B is coupled to the other conductive terminal of the MOS transistor MN_A and the bulk of the MOS transistor MN_P; a gate of the MOS transistor MN_A is coupled to the negative power output terminal P−.

Based on the above configuration, it is ensured that the lower potential from the two input terminals is accurately selected for the bulk of the MOS transistor MN_P, so as to ensure that the MOS transistor MN_P can normally cut off the discharge path and the charge path.

Specifically, as shown in FIGS. 19-21, a working principle of the bulk selection circuit is as follows:

When the potential of the internal negative power supply terminal (VSS node) or the external negative power supply terminal (B− node) is higher than that of the negative power output terminal (P− node), MN_A is turned on and MN_B is turned off. At this time, the bulk selection circuit (Bulk Sel in FIGS. 19-20) selects and outputs the lower potential of the negative power output terminal (P− node) (relative to the internal negative power supply terminal (VSS node) and the external negative power supply terminal (B− node)).

When the potential of the internal negative power supply terminal (VSS node) or the external negative power supply terminal (B− node) is lower than that of the negative power output terminal (P− node), MN_B is turned on and MN_A is turned off. At this time, the bulk selection circuit (Bulk Sel in FIGS. 19-20) outputs the lower potential of the internal negative power supply terminal (VSS node) or the external negative power supply terminal (B− node) (relative to the negative power output terminal (P− node)).

Exemplarily, both the MOS transistor MN_A and the MOS transistor MN_B are also NMOS transistors.

In one embodiment, it further comprises a resistor R1, and the positive power supply terminal is coupled to the positive electrode of the battery cell through the resistor R1.

In this embodiment, based on configuration of the resistor R1, when the battery cell is correctly coupled to the anti-reverse connection power chip, a current flowing into the anti-reverse connection power chip is limited, so as to protect other components (such as the MOS transistor MN_P) inside the anti-reverse connection power chip and prevent overcurrent.

In one embodiment, it further comprises a capacitor C1. One end of the capacitor C1 is coupled to the positive power supply terminal, and the other end of the capacitor C1 is coupled to the internal negative power supply terminal.

In this embodiment, the capacitor C1 is used to stabilize voltage fluctuations and current fluctuations during connection of the battery cell to the anti-reverse connection power chip, prevent transient currents or voltages in the anti-reverse connection power chip, and enhance the control stability of the anti-reverse connection power chip.

In some implementations, the control component is also used to protect the anti-reverse connection power chip, and the protection comprises at least one of the following: overvoltage protection, undervoltage protection, overcurrent protection, short-circuit protection, and temperature protection.

In this embodiment, by enriching the functions of the control component, it can meet the changing control requirements in practical applications, making the use of the anti-reverse connection power chip of the present invention more flexible.

Specifically, overvoltage protection refers to the function of preventing the actual voltage in the anti-reverse connection power chip from exceeding a first voltage threshold. When the actual voltage in the anti-reverse connection power chip exceeds the first voltage threshold, the MOS transistor MN_P will take measures (such as cutting off the power supply or adjusting the output) to prevent the anti-reverse connection power chip from being burned due to excessive voltage.

Undervoltage protection refers to the function of preventing the actual voltage in the anti-reverse connection power chip from being lower than a second voltage threshold. When the actual voltage in the anti-reverse connection power chip is lower than the second voltage threshold, the MOS transistor MN_P will be turned off or reduce the output to prevent the voltage of the battery coupled to the anti-reverse connection power chip from being too low, thereby extending the service life of the battery.

Overcurrent protection refers to the function of preventing the actual current in the anti-reverse connection power chip from exceeding a current threshold. When the actual current in the anti-reverse connection power chip exceeds the current threshold, the MOS transistor MN_P will automatically cut off or limit the current flow to prevent damage to components in the anti-reverse connection power chip.

Short-circuit protection refers to the function of preventing component damage or failure when the anti-reverse connection power chip is short-circuited. When a short-circuit event (such as direct connection of the power supply to the load) is detected in the anti-reverse connection power chip, the MOS transistor MN_P will quickly cut off the power supply to prevent excessive current from damaging components in the anti-reverse connection power chip.

Temperature protection refers to the function of monitoring and controlling the temperature of the anti-reverse connection power chip. When the temperature of the anti-reverse connection power chip exceeds a temperature threshold, the MOS transistor MN_P will take measures (such as reducing power, turning off the device, or issuing an alarm) to prevent overheating and possible component damage.

The present invention also provides a protection circuit for an anti-reverse connection power chip, which comprises the anti-reverse connection power chip according to the foregoing embodiments and a detachable battery cell.

When the battery cell is installed in the protection circuit, and the positive electrode of the battery cell is coupled to the positive power supply terminal of the anti-reverse connection power chip, and the negative electrode of the battery cell is coupled to the external negative power supply terminal of the anti-reverse connection power chip, the battery cell is correctly coupled to the anti-reverse connection power chip, and the anti-reverse connection protection switch is turned on.

When the battery cell is installed in the protection circuit, and the negative electrode of the battery cell is coupled to the positive power supply terminal of the anti-reverse connection power chip, and the positive electrode of the battery cell is coupled to the external negative power supply terminal of the anti-reverse connection power chip, the battery cell is reversely coupled to the anti-reverse connection power chip, and the anti-reverse connection protection switch is turned off.

In one example, an internal circuit of the anti-reverse connection power chip of the present invention is as shown in FIG. 18. In FIG. 18, BAT can be understood as the aforementioned battery cell; B+ can be understood as an external positive power supply terminal; VDD can be understood as the aforementioned positive power supply terminal; B− can be understood as the aforementioned external negative power supply terminal; VSS can be understood as the aforementioned internal negative power supply terminal; C1 can be understood as the aforementioned capacitor C1; MN1 can be understood as the aforementioned anti-reverse connection protection switch (i.e., MOS transistor MN1); MN_P can be understood as the aforementioned first power switch (i.e., MOS transistor MN_P); MP_P can be understood as the aforementioned second power switch (i.e., MOS transistor MP_P); the control component (GATE CONTROL) can be understood as the power control circuit included in the aforementioned anti-reverse connection power chip; D1 is an ESD CELL parasitic diode between VDD and VSS or a parasitic diode of the GATE CONTROL circuit; DB is a parasitic diode from the bulk of MN_P to the drain; D2 is a parasitic diode from the bulk of MP_P to the drain; SW can be understood as the aforementioned node SW; DE is a parasitic diode from other internal devices coupled to SW to VDD.

When the battery cell is correctly coupled to the anti-reverse connection power chip, B+ coupled to the gate of MN1 is at a relatively high potential, MN1 is turned on, the potential of VSS is almost equal to that of B−, all internal circuits of the anti-reverse connection power chip can work normally, and the on-resistance of MN_P is not affected by MN1.

When the battery cell is reversely coupled to the anti-reverse connection power chip, B+ coupled to the gate of MN1 is at the lowest potential in the entire circuit, and the source of NM1 is coupled to the internal VSS, so NM1 is turned off; the parasitic diode from the drain to the source of NM1 is reverse-biased and turned off; the completely turned-off MN1 realizes potential isolation between VSS and B− in the switching power chip.

The potential of the internal VSS is pulled to be very close to the potential of B+ through the unidirectional conduction path formed by D1. At the same time, since GATE CONTROL is powered through the B+ and VSS ports, the gate voltage of MN_P output by it will also be very close to the potential of B+; the gate driving voltage of MN_P turns off its channel, and DB is also reverse-biased and turned off, which makes MN_P completely turned off. Thus, when the battery cell is reversely coupled to the anti-reverse connection power chip, there is no large current path inside the anti-reverse connection power chip that can burn the chip.

In another example, the internal circuit of the anti-reverse connection power chip of the present invention is as shown in FIG. 2 or FIG. 3.

In FIGS. 19 and 20, BAT can be understood as the aforementioned battery cell; B+ can be understood as an external positive power supply terminal; VDD can be understood as the aforementioned positive power supply terminal; B− can be understood as the aforementioned external negative power supply terminal; VSS can be understood as the aforementioned internal negative power supply terminal; C1 can be understood as the aforementioned capacitor; R1 can be understood as the aforementioned capacitor C1; MN1 can be understood as the aforementioned anti-reverse connection protection switch (i.e., MOS transistor MN1); MN_P can be understood as the aforementioned first power switch (i.e., MOS transistor MN_P); MP_P can be understood as the aforementioned second power switch (i.e., MOS transistor MP_P); the control component (PROTECT BLOCK) can be understood as the power protection circuit included in the aforementioned anti-reverse connection power chip; D1 is an ESD CELL parasitic diode between VDD and VSS or a parasitic diode of the control component (PROTECT BLOCK); P− can be understood as the aforementioned negative power output terminal P−; Bulk Sel can be understood as the aforementioned bulk selection circuit.

It should be understood that the power protection circuit supports protection for the anti-reverse connection power chip.

What the power protection circuit has in common with power control circuits (such as buck or boost types) is that both require MN1 to isolate B− from VSS when the power supply is reversely connected, that is, the circuit protection logic when the battery cell is reversely coupled to the anti-reverse connection power chip is consistent.

The difference between the power protection circuit and the power control circuit is that in the power protection circuit, the source of MN1 is not fixedly coupled to B−, VSS, or P−, which causes a change in the source of the lower potential selected by the bulk selection circuit (Bulk Sel).

Specifically, in FIG. 19, Bulk Sel selects the lowest potential between VSS and P− to provide to the source of NM_P; while in FIG. 20, Bulk Sel selects the lowest potential between B− and P− to provide to the source of NM_P. Since NM_P is used to control the current path between B− and P−, both selection methods shown in FIGS. 19 and 20 are feasible.

Further, the specific structure of Bulk Sel in FIGS. 19 and 20 can be as shown in FIG. 21. In FIG. 21, MN_A can be understood as the aforementioned MOS transistor MN_A, and MN_B can be understood as the aforementioned MOS transistor MN_B.

The embodiments of this application are described above in conjunction with the accompanying drawings, but this application is not limited to the specific embodiments described above, the specific embodiments described above are merely illustrative and not limiting, and the person of ordinary skill in the field of this application, without departing from the purpose of the application and the scope of protection of the claims, may also make many forms, all of which are under the protection of this application.

Although preferred embodiments of the present invention have been described, additional changes and modifications to these embodiments may be made once the basic creative concepts are known to those skilled in the art. The appended claims are therefore intended to be interpreted to comprise preferred embodiments and all changes and modifications falling within the scope of this application.

Obviously, a person skilled in the art may make various changes and variations to the application without departing from the spirit and scope of the application. Thus, if these modifications and variations of this application fall within the scope of the claims and their equivalent technologies, the application is also intended to comprise these changes and variations.

What is claimed is:

1. A battery cell reverse connection protection circuit for a chip, comprising:
N series-connected battery cells and a target chip, wherein the target chip comprises N+1 voltage terminals sorted in descending order of electric potential, a positive electrode of a S-th battery cell among the N battery cells is coupled to a S-th voltage terminal among the N+1 voltage terminals, and a negative electrode of the S-th battery cell is coupled to a (S+1)-th voltage terminal among the N+1 voltage terminals; and, the positive electrode of the S-th battery cell is coupled to the S-th voltage terminal through a corresponding anti-reverse connection protection switch, or the negative electrode of the S-th battery cell is coupled to the (S+1)-th voltage terminal through a corresponding anti-reverse connection protection switch;
wherein when one of the battery cells is incorrectly coupled to the target chip, the corresponding anti-reverse connection protection switch is turned off, and when one of the battery cells is normally coupled to the target chip, the corresponding anti-reverse connection protection switch is turned on.

2. The circuit according to claim 1, wherein a control terminal of the anti-reverse connection protection switch corresponding to the positive electrode of the S-th battery cell is coupled to the (S+1)-th voltage terminal, and a control terminal of the anti-reverse connection protection switch corresponding to the negative electrode of the S-th battery cell is coupled to the S-th voltage terminal.

3. The circuit according to claim 2, wherein the anti-reverse connection protection switch corresponding to the positive electrode of the S-th battery cell is a PMOS transistor, and the anti-reverse connection protection switch corresponding to the negative electrode of the S-th battery cell is an NMOS transistor;
a source of the PMOS transistor is coupled to the S-th voltage terminal, a drain of the PMOS transistor is coupled to the positive electrode of the S-th battery cell, and a gate of the PMOS transistor, which is the control terminal of the anti-reverse connection protection switch, is coupled to the (S+1)-th voltage terminal;
a source of the NMOS transistor is coupled to the (S+1)-th voltage terminal, a drain of the NMOS transistor is coupled to the negative electrode of the S-th battery cell, and a gate of the NMOS transistor, which is the control terminal of the anti-reverse connection protection switch, is coupled to the S-th voltage terminal.

4. The circuit according to claim 2, wherein the anti-reverse connection protection switch is disposed inside the target chip; alternatively, the anti-reverse connection protection switch is disposed outside the target chip.

5. A battery cell reverse connection protection circuit for a chip, comprising:
a battery cell and a target chip, wherein the target chip comprises a first voltage terminal and a second voltage terminal; a positive electrode of the battery cell is coupled to the first voltage terminal through a corresponding anti-reverse connection protection switch, or a negative electrode of the battery cell is coupled to the second voltage terminal through a corresponding anti-reverse connection protection switch;
wherein when the battery cell is incorrectly coupled to the target chip, the anti-reverse connection protection switch is turned off, and when the battery cell is normally coupled to the target chip, the anti-reverse connection protection switch is turned on.

6. The circuit according to claim 5, wherein a control terminal of the anti-reverse connection protection switch corresponding to the positive electrode of the battery cell is coupled to the second voltage terminal, and a control terminal of the anti-reverse connection protection switch corresponding to the negative electrode of the battery cell is coupled to the first voltage terminal.

7. The circuit according to claim 6, wherein the anti-reverse connection protection switch corresponding to the positive electrode of the battery cell is a PMOS transistor, a source of the PMOS transistor is coupled to the first voltage terminal, a drain of the PMOS transistor is coupled to the positive electrode of the battery cell, and a gate of the PMOS transistor, which is the control terminal of the anti-reverse connection protection switch, is coupled to the second voltage terminal;
the anti-reverse connection protection switch corresponding to the negative electrode of the battery cell is an NMOS transistor, a source of the NMOS transistor is coupled to the second voltage terminal, a drain of the NMOS transistor is coupled to the negative electrode of the battery cell, and a gate of the NMOS transistor, which is the control terminal of the anti-reverse connection protection switch, is coupled to the first voltage terminal.

8. The circuit according to claim 5, wherein the anti-reverse connection protection switch is disposed inside the target chip; alternatively, the anti-reverse connection protection switch is disposed outside the target chip.

9. A battery cell reverse connection protection circuit, comprising:
a target chip for coupling with a battery cell, comprising a first voltage terminal and a second voltage terminal; and
an anti-reverse connection protection switch;
wherein when the battery cell is normally coupled to the target chip, a positive electrode of the battery cell is coupled to the first voltage terminal through the anti-reverse connection protection switch, and a negative electrode of the battery cell is coupled to the second voltage terminal, or the positive electrode of the battery cell is coupled to the first voltage terminal, and the negative electrode of the battery cell is coupled to the second voltage terminal through the anti-reverse connection protection switch; and
wherein when the battery cell is incorrectly coupled to the target chip, the anti-reverse connection protection switch is turned off, and when the battery cell is normally coupled to the target chip, the anti-reverse connection protection switch is turned on.

10. The circuit according to claim 9, wherein a control terminal of the anti-reverse connection protection switch corresponding to the positive electrode of the battery cell is coupled to the second voltage terminal;
the control terminal of the anti-reverse connection protection switch corresponding to the negative electrode of the battery cell is coupled to the first voltage terminal.

11. The circuit according to claim 10, wherein the anti-reverse connection protection switch is integrated into the target chip or arranged outside the target chip.

12. The circuit according to claim 10, wherein
the anti-reverse connection protection switch of the target chip corresponding to the positive electrode of the battery cell is a PMOS transistor, a source of the PMOS transistor is coupled to the first voltage terminal, a drain of the PMOS transistor is coupled to the positive electrode of the battery cell, and a gate of the PMOS transistor, which is the control terminal of the anti-reverse connection protection switch, is coupled to the second voltage terminal; or
the anti-reverse connection protection switch of the target chip corresponding to the negative electrode of the battery cell is an NMOS transistor, a source of the NMOS transistor is coupled to the second voltage terminal, a drain of the NMOS transistor is coupled to the negative electrode of the corresponding battery cell, and a gate of the NMOS transistor, which is the control terminal of the anti-reverse connection protection switch, is coupled to the first voltage terminal.

13. The circuit according to claim 10, wherein the target chip is a battery protection chip.

14. An anti-reverse connection chip, comprising:
a positive power supply terminal for coupling to a positive electrode of a battery cell;
an external negative power supply terminal for coupling to a negative electrode of the battery cell;
an internal negative power supply terminal;
an anti-reverse connection protection switch coupled between the external negative power supply terminal and the internal negative power supply terminal, with its control terminal coupled to the positive power supply terminal;
a control component coupled between the positive power supply terminal and the internal negative power supply terminal, and comprising a control output terminal; and
a power switch comprising one conductive terminal coupled to the external negative power supply terminal, and a control terminal coupled to the control output terminal of the control component;
wherein when the battery cell is reversely coupled to the anti-reverse connection power chip, the anti-reverse connection protection switch is turned off; when the battery cell is correctly coupled to the anti-reverse connection power chip, the anti-reverse connection protection switch is turned on.

15. The anti-reverse connection power chip according to claim 14, wherein the anti-reverse connection protection switch is a MOS transistor MN1, one conductive terminal of the MOS transistor MN1 is coupled to the internal negative power supply terminal, the other conductive terminal of the MOS transistor MN1 is coupled to the external negative power supply terminal, a gate of the MOS transistor MN1, as the control terminal of the anti-reverse connection protection switch, is coupled to the positive power supply terminal, and a bulk of the MOS transistor MN1 is coupled to the internal negative power supply terminal;
the power switch is a MOS transistor MN_P, one conductive terminal of the MOS transistor MN_P is coupled to the external negative power supply terminal, and a gate of the MOS transistor MN_P, as the control terminal, is coupled to the control output terminal of the control component.

16. The anti-reverse connection power chip according to claim 15, further comprising a second power switch, wherein the aforementioned power switch is referred to as the first power switch;
the first power switch is a MOS transistor MN_P, one conductive terminal of the MOS transistor MN_P is coupled to the external negative power supply terminal, a gate of the MOS transistor MN_P, as a control terminal, is coupled to one control output terminal of the control component, the other conductive terminal of the MOS transistor MN_P is coupled to a node SW, and a bulk of the MOS transistor MN_P is coupled to the internal negative power supply terminal;
the second power switch is a MOS transistor MP_P, one conductive terminal of the MOS transistor MP_P is coupled to the positive power supply terminal, a gate of the MOS transistor MP_P, as a control terminal, is coupled to another control output terminal of the control component, the other conductive terminal of the MOS transistor MP_P is coupled to the node SW, and a bulk of the MOS transistor MN_P is coupled to the positive power supply terminal;
the node SW is coupled to an inductor.

17. The anti-reverse connection power chip according to claim 16, wherein the control component converts an input voltage into an output voltage by controlling the first power switch and the second power switch to be turned on alternately.

18. The anti-reverse connection power chip according to claim 15, wherein the other conductive terminal of the MOS transistor MN_P is coupled to a negative power output terminal P−;
the anti-reverse connection power chip further comprises a bulk selection circuit comprising a first input terminal coupled to the negative power output terminal P−, and a second input terminal coupled to the internal negative power supply terminal or the external negative power supply terminal, and an output terminal coupled to the bulk of the MOS transistor MN_P, and the bulk selection circuit selects lower potential from the two input terminals and provides it to the bulk of the MOS transistor MN_P.

19. The anti-reverse connection power chip according to claim 18, wherein the negative power output terminal P− is coupled to an input terminal of the control component;
the control component realizes charge and discharge protection by controlling conduction or disconnection of the power switch.

20. The anti-reverse connection power chip according to claim 18, wherein the bulk selection circuit comprises MOS transistors MN_A and MN_B;
one conductive terminal of the MOS transistor MN_A, as one input terminal of the bulk selection circuit, is coupled to the negative power output terminal P−, the other conductive terminal of the MOS transistor MN_A is coupled to the bulk of the MOS transistor MN_P, and a gate of the MOS transistor MN_A is coupled to the internal negative power supply terminal or the external negative power supply terminal;
one conductive terminal of the MOS transistor MN_B, as the other input terminal of the bulk selection circuit, is coupled to the internal negative power supply terminal or the external negative power supply terminal, the other conductive terminal of the MOS transistor MN_B is coupled to the other conductive terminal of the MOS transistor MN_A and the bulk of the MOS transistor MN_P, and a gate of the MOS transistor MN_A is coupled to the negative power output terminal P−.
